(19) United States
(12) Patent Application Publication
(10) Pub. No.: US 2016/0357148 A1
(43) Pub. Date: Dec. 8, 2016

(54) OPTIMISED TIMEPIECE BARREL

(71) Applicant: ETA SA MANUFACTURE HORLOGERE SUISSE, Grenchen (CH)

(72) Inventors: Sebastien KAESER, Bevaix (CH); Serge NICOUD, Le Landeron (CH); Marc RÖTHLISBERGER, Bern (CH)

(73) Assignee: ETA SA MANUFACTURE HORLOGERE SUISSE, Grenchen (CH)

(21) Appl. No.: 15/106,515

(22) PCT Filed: Dec. 2, 2014
(86) PCT No.: PCT/EP2014/076225

§ 371 Date: Jun. 20, 2016

(30) Foreign Application Priority Data
Dec. 20, 2013 (EP) 13198806.5

(51) Int. Cl. G04B 1/16; C23C 16/26; C23C 14/06; G04D 99/00

(52) U.S. Cl. CPC G04B 1/16; G04D 99/00; C23C 16/26; C23C 14/0605

(57) ABSTRACT

A method for producing a timepiece barrel including a drum with a first spring bearing surface of a chamber including a spring, including a bore for guiding a core and bordered by an inner abutment surface and by an outer abutment surface, the spring bearing surface on the side of the chamber including a DLC coating and the bore is thus masked to avoid any DLC coating, and, either at least the inner abutment surface or the outer abutment surface is devoid of any DLC coating, or all of the surfaces of the drum include a DLC coating, with the exception of the first bore, which is devoid of any DLC coating, after a DLC treatment is effected over the entire drum with the exception of the masked areas.

### FIELD OF THE INVENTION

The invention concerns a timepiece barrel comprising at least one drum for receiving at least one spirally wound spring inside a chamber partially delimited by a first spring bearing surface, and said drum comprising at least a first bore guiding the pivoting of a core or of an arbor, said first bore is bordered on one side by a first inner abutment surface adjacent to said first spring bearing surface, and on the other side by a first outer abutment surface.

The invention concerns a timepiece movement including at least one such barrel.

The invention concerns a timepiece including at least one such movement, and/or at least one such barrel.

The invention concerns a method for producing a timepiece barrel for the protection of said barrel against wear due to friction against the spring.

The invention concerns the field of timepiece mechanisms comprising springs in friction contact, and more specifically mainspring barrels and striking barrels.

### BACKGROUND OF THE INVENTION

The barrel is the energy reserve of a mechanical watch. It comprises in particular a drum, which cooperates with a gear train and which is arranged to receive, in an inner chamber, at least one spiral spring which is hooked at its inner end to an arbor or to a core. The chamber for receiving the spring, or springs if there are more than one, is generally closed by a cover, or directly by the ratchet-wheel that is usually on the arbor or on the core.

The drum and, depending on the case, the cover or the ratchet-wheel, may be coated with a DLC treatment or another antiwear treatment, particularly a PVD or CVD coating, in order to improve its lifetime, by reducing wear on the inner surfaces caused by friction of the mainspring. The reliability of the product is then also improved.

Observation of the performance over time of barrels protected in this manner reveals that, due to the intrinsic properties of such treatments, whether they are surface or core treatments or coating, spraying or other treatments (all of which will be referred to hereafter as “treatments”), premature wear may occur where they pivot due to the surface and tribological properties of the antiwear treated areas, which may damage the pivot axis or suchlike.

WO Patent Application 2013/132076 A1 in the name of SOWIND SA discloses a barrel comprising two superposed chambers inside the same drum, with two ratchet-wheel covers, one of which is integral with a second hub for the second chamber coaxial to the first hub for the first chamber.

### SUMMARY OF THE INVENTION

The invention proposes to produce barrels with good resistance to wear with any type of spring, and good resistance to wear at the pivots.

To this end, the invention concerns a timepiece barrel comprising at least one drum for receiving at least one spirally wound spring inside a chamber partially delimited by a first spring bearing surface, and said drum comprising at least a first bore guiding the pivoting of a core or of an arbor, said first bore is bordered on one side by a first inner abutment surface adjacent to said first spring bearing surface, and on the other side by a first outer abutment surface, characterized in that at least said first spring bearing surface on the side of said chamber includes a DLC coating to resist wear during friction against said spring, and in that said first bore is devoid of any DLC coating.

The invention concerns a timepiece movement including at least one such barrel.

The invention concerns a timepiece including at least one such movement, and/or at least one such barrel.

The invention concerns a method for producing a timepiece barrel for the protection of said barrel against wear due to friction against the spring, characterized in that:
a drum is made comprising a first spring bearing surface on the side of a chamber for receiving a spring, said drum comprising at least a first bore bordered on one side by a first inner abutment surface adjacent to said first inner side wall, and on the other side by a first outer abutment surface;
at least said first bore is masked to avoid the action of a DLC treatment;
a DLC treatment is effected over said entire drum with the exception of the area thus masked.

### BRIEF DESCRIPTION OF THE DRAWINGS

Other features and advantages of the invention will appear upon reading the following detailed description, with reference to the annexed drawings, in which:

FIG. 1 illustrates, in a schematic cross-section through the pivot axis, a barrel according to the invention, comprising a drum closed by a cover.

FIG. 2 shows a schematic perspective view of the barrel drum of FIG. 1, viewed from the outside opposite the spring receiving chamber.

FIG. 3 shows a schematic perspective view of the barrel drum of FIG. 1, viewed from the inside of the spring receiving chamber;

FIG. 4 shows a schematic perspective view of the barrel cover of FIG. 1, viewed from the inside of the spring receiving chamber.

FIG. 5 shows a schematic perspective view of the barrel cover of FIG. 1, viewed from the outside opposite the spring receiving chamber.

FIG. 6 shows a schematic cross-sectional view, through the pivot axis, of the barrel drum of FIG. 1 equipped with a masking tool and mounted on a holding tool for the anti-wear treatment of the drum.

FIG. 7 shows a schematic cross-sectional view, through the pivot axis, of the barrel cover of FIG. 1 equipped with a masking tool and mounted on a holding tool for the anti-wear treatment of the cover.

FIGS. 8 to 10 illustrate, in cross-sectional views through the pivot axis, different non-limiting variants of the barrel of the invention:

FIG. 8 with an arbor forming a core on which the drum pivots and which carries a ratchet-wheel closing the spring chamber;

FIG. 9 with a smooth arbor on which the drum pivots and which carries a core and a sleeve for driving a cover for closing the spring chamber;

FIG. 10 with a smooth arbor on which the drum pivots and which carries a core and drives a cover for closing the spring chamber.

FIG. 11 shows a block diagram of a timepiece including a movement comprising a barrel according to the invention.

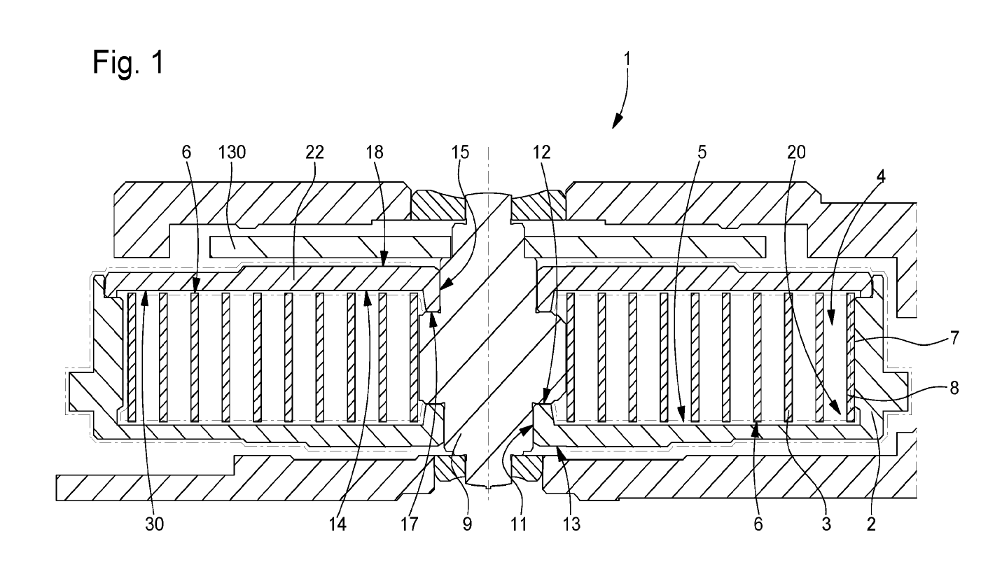

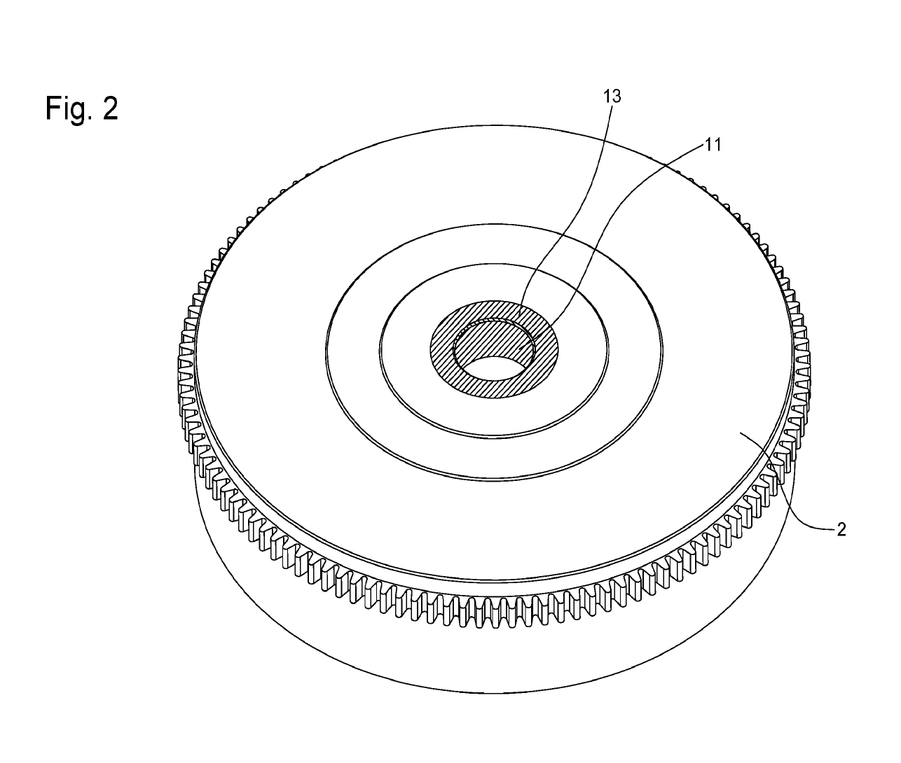

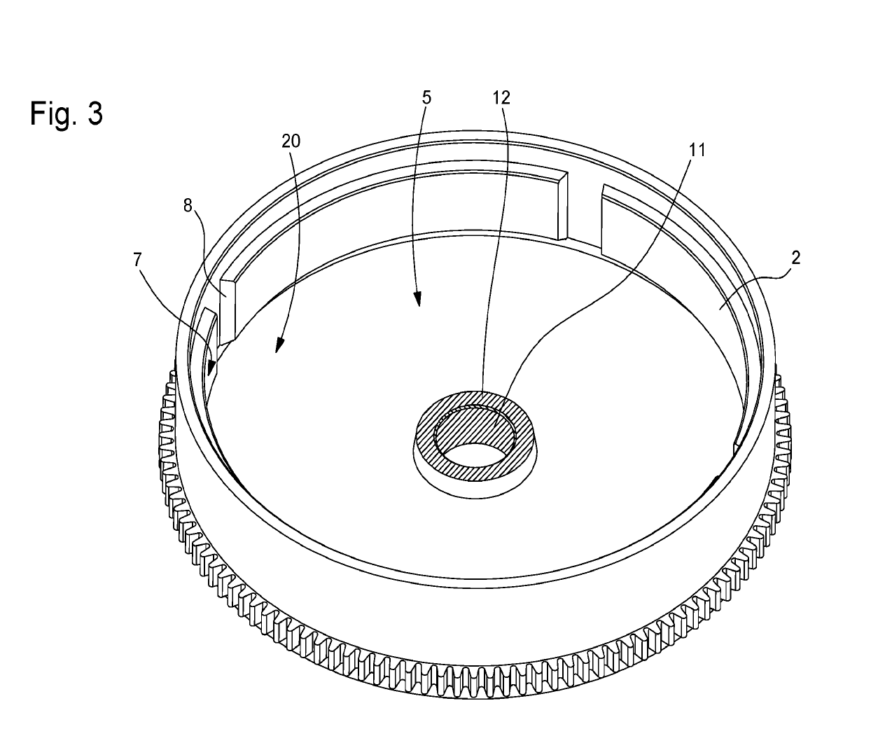

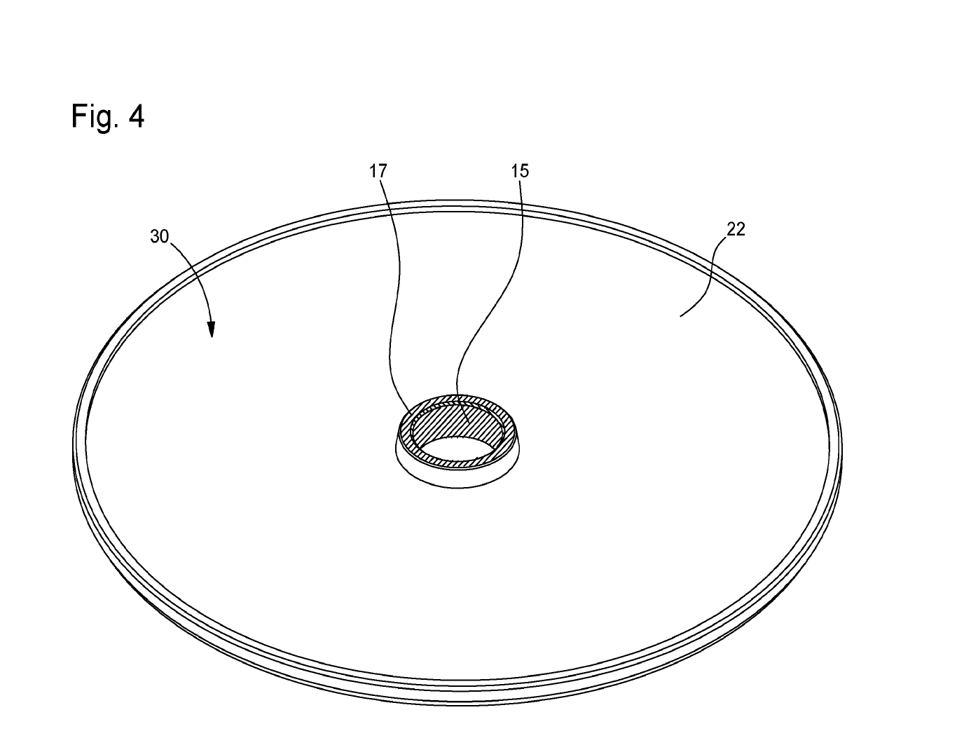

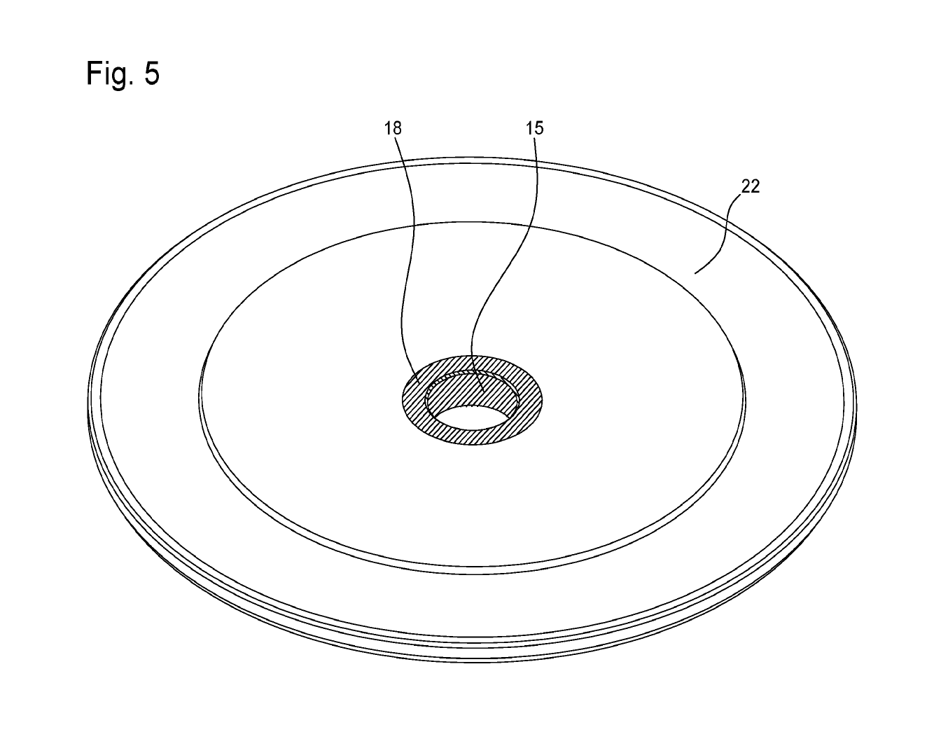

### DETAILED DESCRIPTION OF PREFERRED EMBODIMENTS

The invention concerns the field of timepiece mechanisms comprising springs in friction contact, and more specifically mainspring barrels and striking barrels.

To prevent problems of wear at the pivoting areas, antiwear treatments giving the material a high hardness must be avoided on the surfaces where pivoting occurs (arbor bores, bearing surfaces), regardless of whether these treatments are heat or induction treatments, surface treatments, coatings, spraying or other treatments, all of which are referred to hereafter as “treatments”. More specifically, when, advantageously, surfaces likely to be in friction contact against the spring are protected by a DLC or similar treatment, the invention avoids depositing even a limited amount of the DLC or any other PVD/CVD coating (and similar methods) in the pivot, ensuring imperviousness to the carrier gas during the process for depositing the bonding layer and sub-layers.

The invention therefore concerns a timepiece barrel 1 comprising at least one drum 2 for receiving at least one spirally wound spring 3 inside a chamber 4 partially delimited by a first spring bearing surface 20. This first spring bearing surface 20 includes either a first inner side wall 5 of drum 2 facing an edge 6 of at least one such spring 3, or an inner peripheral surface 7 (on which drum 2 generally includes peripheral means 8 for hooking a spring 3), or preferably both this first inner side wall 5 and inner peripheral wall 7. The invention is more particularly described in this latter alternative. Those skilled in the art will know how to extrapolate to only one of surfaces 5 and 7.

Drum 2 includes at least first bore 11 for guiding the pivoting of a core 9 or of an arbor 10. This first bore 11 is bordered on one side by a first inner abutment surface 12 adjacent to the first inner side wall 5, and on the other side by a first outer abutment surface 13.

According to the invention, at least the first spring bearing surface 20 includes a DLC coating to resist wear during friction with spring 3, and at least the first bore 11 is devoid of any DLC coating.

In a particular embodiment, the first bore 11, the first inner abutment surface 12 is devoid of any DLC coating.

In a particular embodiment, the first outer abutment surface 13 is devoid of any DLC coating.

In a particular embodiment, the first bore 11, the first inner abutment surface 12 and the first outer abutment surface 13 are devoid of any DLC coating.

In a particular advantageous embodiment, all of the surfaces of drum 2 include a DLC coating, with the exception of first bore 11, which is devoid of any DLC coating.

In a particular embodiment, all of the surfaces of drum 2 include a DLC coating, with the exception of first bore 11 and of first inner abutment surface 12 which are devoid of any DLC coating.

In a particular embodiment, all of the surfaces of drum 2 include a DLC coating, with the exception of first bore 11 and of first outer abutment surface 13 which are devoid of any DLC coating.

In a particularly advantageous embodiment, all of the surfaces of drum 2 include a DLC coating, with the exception of first bore 11 and of first inner abutment surface 12 and of first outer abutment surface 13, which are devoid of any DLC coating.

In a particular embodiment, first bore 11 is treated with an anodizing treatment when drum 2 is made from aluminium alloy, or a coating with one or more of the following: Au, Ni, NiP, doped Ni, Cr, CrN, Sn, Ta, when drum 2 is made of a material other than an aluminium alloy.

In a particular embodiment, first bore 11 and first inner abutment surface 12 include an anodizing treatment when drum 2 is made from aluminium alloy, or include a coating of one or more of the following: Au, Ni, NiP, doped Ni, Cr, CrN, Sn, Ta, when drum 2 is made of a material other than an aluminium alloy.

In a particular embodiment, first bore 11 and first outer abutment surface 13 include an anodizing treatment when drum 2 is made from aluminium alloy, or include a coating of one or more of the following: Au, Ni, NiP, doped Ni, Cr, CrN, Sn, Ta, when drum 2 is made of a material other than an aluminium alloy.

In a particular embodiment, first bore 11, first inner abutment surface 12 and first outer abutment surface 13 include an anodizing treatment when drum 2 is made from aluminium alloy, or include a coating of one or more of the following: Au, Ni, NiP, doped Ni, Cr, CrN, Sn, Ta, when drum 2 is made of a material other than an aluminium alloy.

In a particular embodiment, said first bore 11 includes a coating which is different from the coating of said first inner abutment surface.

The mode of protection applied to drum 2 is applicable to the cover 22 or ratchet-wheel 130, depending on the case, which closes the chamber 4 for receiving spring 3, or springs 3 if there are several.

Thus, advantageously, for closing chamber 4, on the opposite side to first inner side wall 5, barrel 1 includes a cover 22 or a ratchet-wheel 130 comprising a second spring bearing surface 30. This second spring bearing surface 30 includes, in particular, a second inner side wall 14, opposite to first inner side wall 5. Cover 22 or ratchet-wheel 130 includes a second bore 15 for guiding the pivoting of a core 9 or of an arbor 10, or of a sleeve 16, depending on the configuration of barrel 1.

Cover 22 or ratchet-wheel 130 closing chamber 4 preferably includes a second inner abutment surface 17, adjacent on one side to second spring bearing surface 30, particularly to second inner side wall 14, and on the other side to second bore 15.

Likewise, cover 22 or ratchet-wheel 130 closing chamber 4 includes a second outer abutment surface 18, adjacent to second bore 15 and opposite chamber 4.

In a particular embodiment of the invention, at least second spring surface 30, notably the surface of second inner side wall 14 on the side of chamber 4, includes a DLC coating to resist wear during friction against the spring 3 or springs 3 if there are several.

In a particular embodiment, this second bore 15 is devoid of any DLC coating.

In a particular embodiment, the second inner abutment surface 17 is devoid of any DLC coating.

In a particular embodiment, the second outer abutment surface 18 is advantageously devoid of any DLC coating.

In a particular embodiment, second bore 15, second inner abutment surface 17, and second outer abutment surface 18 are devoid of any DLC coating.

In a particular embodiment, all of the surfaces of cover 22 or of ratchet-wheel 130 closing chamber 4 include a DLC coating, with the exception of second bore 15, which is devoid of any DLC coating.

In a particular embodiment, all of the surfaces of cover 22 or of ratchet-wheel 130 closing chamber 4 include an antiwear coating or a DLC coating, with the exception of first bore 15 and of second inner abutment surface 17, which are devoid of any DLC coating.

In a particular embodiment, all of the surfaces of cover 22 or of ratchet-wheel 130 closing chamber 4 include an antiwear coating or a DLC coating, with the exception of second bore 15 and of second outer abutment surface 18, which are devoid of any antiwear coating and any DLC coating.

In a particular embodiment, all of the surfaces of cover 22 or of ratchet-wheel 130 closing chamber 4 include an antiwear coating or a DLC coating, with the exception of second bore 15 and of second inner abutment surface 17 and of second outer abutment surface 18, which are devoid of any antiwear coating and any DLC coating.

In a particular embodiment, second bore 15 includes an anodizing treatment when cover 22 or ratchet-wheel 130 is made from aluminium alloy, or a coating of one or more of the following: Au, Ni, NiP, doped Ni, Cr, CrN, Sn, Ta, when cover 22 or ratchet-wheel 130 is made of a material other than an aluminium alloy.

In a particular embodiment, second bore 15 and second inner abutment surface 17 are treated with an anodizing treatment when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular embodiment, second bore 15 and second outer abutment surface 18 are treated with an anodizing treatment when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular embodiment, second bore 15, second inner abutment surface 17 and second outer abutment surface 18 are treated with an anodizing treatment when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular embodiment, second bore 15 includes a coating which is different from the coating of the second inner abutment surface 17 and/or of the second outer abutment surface 18.

The invention also concerns a timepiece movement 100 including at least one such barrel 1.

The invention also concerns a timepiece 200 incorporating at least one such movement 100, and/or at least one such barrel 1.

The invention also concerns a method for producing a timepiece barrel 1 for the protection of said barrel against wear due to friction against a spring. According to this method:
a drum 2 is made comprising a first spring bearing surface 20, drum 2 including at least a first bore 11 bordered on one side by a first inner abutment surface 12 adjacent to first spring bearing surface 20, and on the other side by a first outer abutment surface 13;
at least the first bore 11 is masked to avoid the action of a DLC treatment;
a DLC treatment is effected over the entire drum 2, with the exception of the area thus masked.

In a particular implementation of the method, when first bore 11 is masked, the first inner abutment surface 12 is also masked.

In a particular implementation of the method, when first bore 11 is masked, the first outer abutment surface 13 is also masked.

In a particular implementation, drum 2 is made of brass or nickel silver or aluminium alloy.

In a particular implementation, an anodizing treatment is effected in first bore 11 when drum 2 is made from aluminium alloy, or a coating with one or more of the following: Au, Ni, NiP, doped Ni, Cr, CrN, Sn, Ta, when drum 2 is made of a material other than an aluminium alloy.

In a particular implementation, an anodizing treatment is effected in first bore 11 and first inner abutment surface 12 when drum 2 is made from aluminium alloy, or a coating with one or more of the following: Au, Ni, NiP, doped Ni, Cr, CrN, Sn, Ta, when drum 2 is made of a material other than an aluminium alloy.

In a particular implementation, an anodizing treatment is effected in first bore 11 and on first outer abutment surface 13 when drum 2 is made from aluminium alloy, or a coating with one or more of the following: Au, Ni, NiP, doped Ni, Cr, CrN, Sn, Ta, when drum 2 is made of a material other than an aluminium alloy.

In a particular implementation, an anodizing treatment is effected in first bore 11, first inner abutment surface 12 and first outer abutment surface 13 when drum 2 is made from aluminium alloy, or a coating with one or more of the following: Au, Ni, NiP, doped Ni, Cr, CrN, Sn, Ta, when drum 2 is made of a material other than an aluminium alloy.

In a particular embodiment, a coating is made in first bore 11 which is different from another coating treatment made on first inner abutment surface 12 and/or first outer abutment surface 13.

In a particular implementation of this method, in order to close a chamber 4 for receiving at least one spring, there is also made a cover 22 or a ratchet-wheel 130 including a second spring bearing surface 30 and a second bore 15 bordered on one side by a second inner abutment surface 17, and on the other side by a second outer abutment surface 18; and
at least the second bore 15 is masked to avoid the action of a DLC treatment;
a DLC treatment is effected over the entire cover 22 or ratchet-wheel 130, with the exception of the area thus masked.

In a particular implementation of the method, when second bore 15 is masked, the first inner abutment surface 17 is also masked.

In a particular implementation of the method, when second bore 15 is masked, the second outer abutment surface 18 is also masked.

In a particular implementation, cover 22 or ratchet-wheel 130 is made of brass or nickel silver or aluminium alloy.

In a particular implementation, an anodizing treatment is effected in second bore 15 when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular implementation, an anodizing treatment is effected in second bore 15 and second inner abutment surface 17 when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular implementation, an anodizing treatment is effected in second bore 15 and second outer abutment surface 18 when cover 22 or ratchet-wheel 130 is made from aluminium alloy, or a coating with one or more of the following: Au, Ni, NiP, doped Ni, Cr, CrN, Sn, Ta, when cover 22 or ratchet-wheel 130 is made of a material other than an aluminium alloy.

In a particular embodiment, a coating is made in second bore 15 which is different from another coating treatment made on second inner abutment surface 17 and/or second outer abutment surface 18.

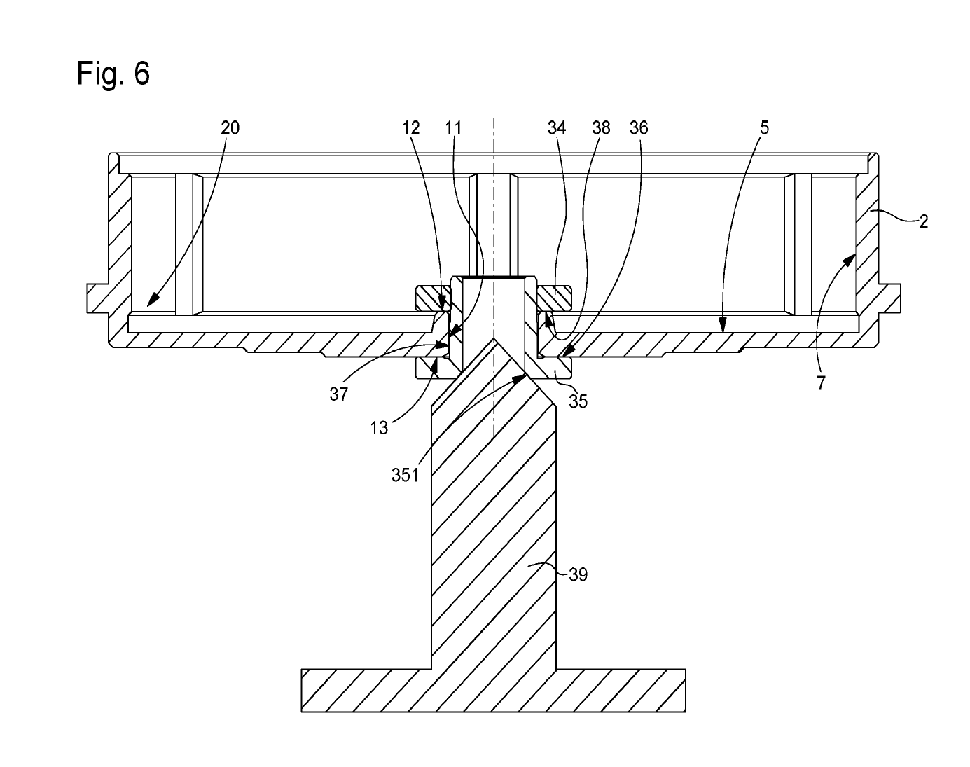

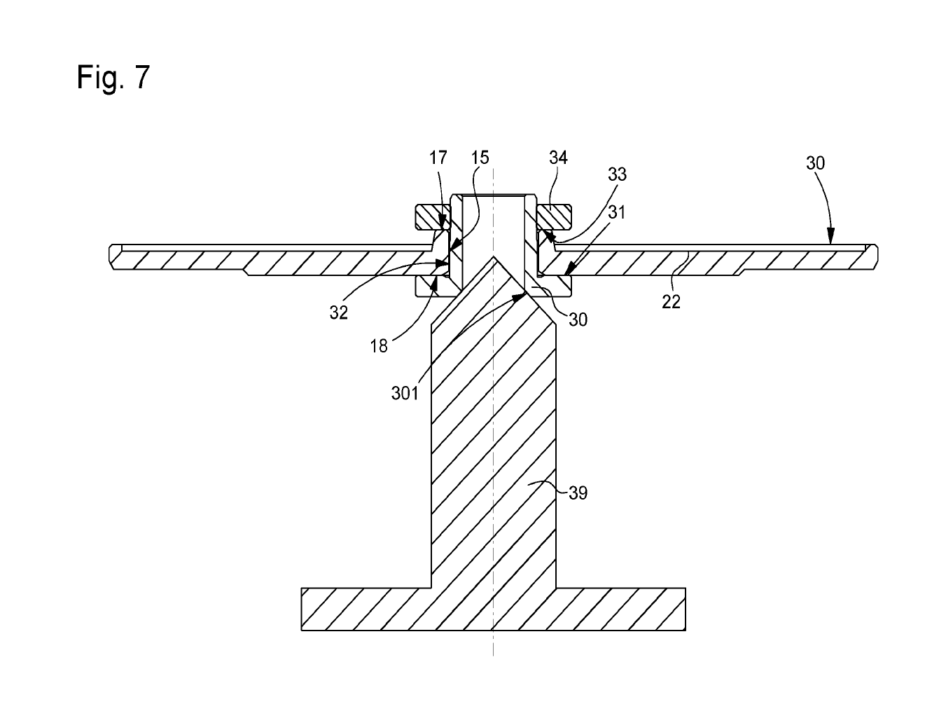

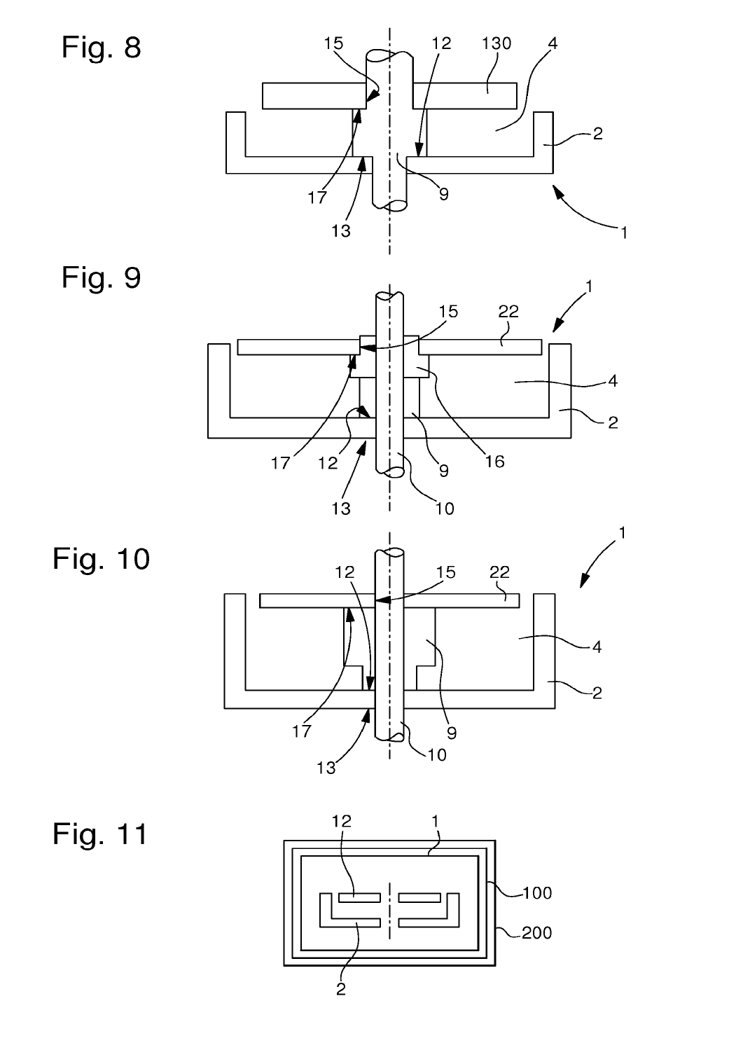

FIGS. 6 and 7 illustrate tools for achieving the antiwear treatment, notably DLC, with means for masking the bores and adjacent bearing surfaces:
for drum 2, in FIG. 6, a conductive stepped ring 35, notably made of brass, is slidably mounted with a shoulder 37 inside bore 11 of drum 2, bearing, via a front surface 36, on first outer abutment surface 13. A conductive ring 34 is driven onto this stepped ring 35 and bears, via a front surface 38, on first inner abutment surface 12. Stepped ring 35 is supported by a conductive support 39 including a conical shoulder on which a chamfer 351 of stepped ring 35 rests. Preferably, drum 2 is made of brass or similar material;
similarly, for cover 22, in FIG. 7, a conductive stepped ring 30, notably made of brass, is slidably mounted with a shoulder 32 inside bore 15 of cover 22, bearing, via a front surface 31, on first outer abutment surface 18. A conductive ring 34 is driven onto this stepped ring 30 and bears, via a front surface 33, on second inner abutment surface 17. Stepped ring 30 is supported by a conductive support 39 including a conical shoulder on which a chamfer 301 of stepped ring 30 rests. Preferably, cover 22 is made of brass or similar material;

1-45. (canceled)

46. A timepiece barrel comprising:
at least one drum for receiving at least one spirally wound spring inside a chamber partially delimited by a first spring bearing surface, and
the drum including at least a first bore guiding pivoting of a core or of an arbor, the first bore is bordered on a first side by a first inner abutment surface adjacent to the first spring bearing surface, and on a second side by a first outer abutment surface,
wherein at least the first spring bearing surface on the side of the chamber includes a DLC coating to resist wear during friction with the spring, and wherein the first bore is devoid of any DLC coating, and
wherein, either at least the first inner abutment surface or the first outer abutment surface is devoid of any DLC coating, or all of surfaces of the drum include a DLC coating, with the exception of the first bore which is devoid of any DLC coating.

47. The barrel according to claim 46, wherein the first inner abutment surface and the first outer abutment surface are devoid of any DLC coating.

48. The barrel according to claim 46, wherein all of the surfaces of the drum include a DLC coating, with the exception of the first bore and of the first inner abutment surface which are devoid of any DLC coating.

49. The barrel according to claim 46, wherein all of the surfaces of the drum include a DLC coating, with the exception of the first bore and of the first outer abutment surface which are devoid of any DLC coating.

50. The barrel according to claim 46, wherein all of the surfaces of the drum include a DLC coating, with the exception of the first bore and of the first inner abutment surface and of the first outer abutment surface which are devoid of any DLC coating.

51. The barrel according to claim 46, wherein the first bore includes an anodizing treatment when the drum is made of aluminium alloy.

52. The barrel according to claim 46, wherein the first bore includes a coating of one or more of: Au, Ni, NiP, doped Ni, Cr, CrN, Sn, Ta, when the drum is made of a material other than aluminium alloy.

53. The barrel according to claim 51, wherein the first inner abutment surface includes an anodizing treatment when the drum is made of aluminium alloy.

54. The barrel according to claim 52, wherein the first inner abutment surface includes a coating of one or more of: Au, Ni, NiP, doped Ni, Cr, CrN, Sn, Ta, when the drum is made of a material other than aluminium alloy.

55. The barrel according to claim 51, wherein the first outer abutment surface includes an anodizing treatment when the drum is made of aluminium alloy.

56. The barrel according to claim 52, wherein the first outer abutment surface includes a coating of one or more of: Au, Ni, NiP, doped Ni, Cr, CrN, Sn, Ta, when the drum is made of a material other than aluminium alloy.

57. The barrel according to claim 46, wherein the first bore includes a coating which is different from the coating of the first inner abutment surface and/or of the first outer abutment surface.

58. The barrel according to claim 46, wherein, to close the chamber, on the side opposite to a first inner side wall, the barrel includes a cover or a ratchet-wheel including a second spring bearing surface and including a second bore for guiding the pivoting of a core or of an arbor or of a sleeve, wherein the cover or the ratchet-wheel closing the chamber includes a second inner abutment surface adjacent to the second spring bearing surface and to the second bore, and a second outer abutment surface adjacent to the second bore and opposite to the chamber, and
wherein at least the surface of the second spring bearing surface on the side of the chamber includes a DLC coating to resist wear during friction with the at least one spring, wherein the second bore is devoid of any DLC coating, and wherein, either at least the second inner abutment surface or the second outer abutment surface is devoid of any DLC coating, or all of surfaces of the cover or of the ratchet-wheel include a DLC coating, with the exception of the second bore which is devoid of any DLC coating.

59. The barrel according to claim 58, wherein the second inner abutment surface and the second outer abutment surface are devoid of any DLC coating.

60. The barrel according to claim 58, wherein all of the surfaces of the cover or of the ratchet-wheel include a DLC coating, with the exception of the second bore and of the second outer abutment surface which are devoid of any DLC coating.

61. The barrel according to claim 58, wherein all of the surfaces of the cover or of the ratchet-wheel closing the chamber include a DLC coating, with the exception of the second bore and of the second outer abutment surface which are devoid of any DLC coating.

62. The barrel according to claim 58, wherein all of the surfaces of the cover or of the ratchet-wheel closing the chamber include a DLC coating, with the exception of the second bore, of the second inner abutment surface and of the second outer abutment surface which are devoid of any DLC coating.

63. The barrel according to claim 58, wherein the second bore includes an anodizing treatment when the cover or the ratchet-wheel is made of aluminium alloy.

64. The barrel according to claim 58, wherein the second bore includes a coating of one or more of: Au, Ni, NiP, doped Ni, Cr, CrN, Sn, Ta, when the cover or the ratchet-wheel is made of a material other than an aluminium alloy.

65. The barrel according to claim 63, wherein the second bore and the second inner abutment surface include an anodizing treatment when the cover or the ratchet-wheel is made of aluminium alloy.

66. The barrel according to claim 64, wherein the second bore and the second inner abutment surface include a coating of one or more of: Au, Ni, NiP, doped Ni, Cr, CrN, Sn, Ta, when the cover or the ratchet-wheel is made of a material other than an aluminium alloy.

67. The barrel according to claim 63, wherein the second bore and the second outer abutment surface include an anodizing treatment when the cover or the ratchet-wheel is made of aluminium alloy.

68. The barrel according to claim 64, wherein the second bore and the second outer abutment surface include a coating of one or more of: Au, Ni, NiP, doped Ni, Cr, CrN, Sn, Ta, when the cover or the ratchet-wheel is made of a material other than an aluminium alloy.

69. The barrel according to claim 58, wherein the second bore includes a coating which is different from the coating of the second inner abutment surface and/or of the second outer abutment surface.

70. A timepiece movement including at least one barrel according to claim 46.

71. A timepiece including at least one movement according to claim 70.

72. A method for producing a timepiece barrel for protection of the barrel against wear due to friction against a spring, the method comprising:
making a drum comprising a first spring bearing surface on a side of a chamber for receiving a spring, the drum including at least a first bore bordered on a first side by a first inner abutment surface adjacent to a first inner side wall, and on a second side by a first outer abutment surface;
masking at least the first bore to avoid action of a DLC treatment;
effecting a DLC treatment on the entire drum with the exception of the first bore, or at least the first inner abutment surface or the first outer abutment surface is masked, and a DLC treatment is effected on the entire drum with the exception of the areas thus masked.

73. The method according to claim 72, wherein the drum is made of brass or nickel silver or aluminium alloy.

74. The method according to claim 72, wherein an anodizing treatment is effected in the second bore when the drum is made from aluminium alloy, or a coating with one or more of the following: Au, Ni, NiP, doped Ni, Cr, CrN, Sn, Ta, when the drum is made of a material other than an aluminium alloy.

75. The method according to claim 74, wherein an anodizing treatment is effected on the first inner abutment surface and/or the first outer abutment surface when the drum is made from aluminium alloy, or a coating with one or more of the following: Au, Ni, NiP, doped Ni, Cr, CrN, Sn, Ta, when the drum is made of a material other than an aluminium alloy.

76. The method according to claim 72, wherein a coating is made in the first bore which is different from another coating made on the first inner abutment surface and/or the first outer abutment surface.

77. The method according to claim 72, wherein, to close a chamber for receiving at least one spring, a cover or a ratchet-wheel is made including a second spring bearing surface and a second bore bordered on a first side by a second inner abutment surface, and on a second side by a second outer abutment surface; and wherein:
at least the second bore is masked to avoid the action of a DLC treatment;
either a DLC treatment is effected on the entire cover or ratchet-wheel with the exception of the second bore, or at least the second inner abutment surface or the second outer abutment surface is also masked, and a DLC treatment is effected on the entire cover or ratchet-wheel with the exception of the areas thus masked.

78. The method according to claim 77, wherein the cover or ratchet-wheel is made of brass or nickel silver or aluminium alloy.

79. The method according to claim 77, wherein an anodizing treatment is effected in the second bore when the cover or the ratchet-wheel is made from aluminium alloy, or a coating with one or more of the following: Au, Ni, NiP, doped Ni, Cr, CrN, Sn, Ta, when the cover or the ratchet-wheel is made of a material other than an aluminium alloy.

80. The method according to claim 79, wherein an anodizing treatment is effected on the second inner abutment surface and/or the second outer abutment surface when the cover or the ratchet-wheel is made from aluminium alloy, or a coating with one or more of the following: Au, Ni, NiP, doped Ni, Cr, CrN, Sn, Ta, when the cover or the ratchet-wheel is made of a material other than an aluminium alloy.

81. The method according to claim 77, wherein a coating is made in the second bore which is different from another coating made on the second inner abutment surface and/or the second outer abutment surface.
